(19) United States
(12) Patent Application Publication
(10) Pub. No.: US 2025/0147099 A1
(43) Pub. Date: May 8, 2025

(54) IC TESTING APPARATUS WITH ELASTIC CONDUCTIVE PILLARS AND ITS MANUFACTURING METHOD

(71) Applicant: He Chou Technology INC., Hsinchu City (TW)

(72) Inventors: WEI-BEEN YU, Hsinchu City (TW); SHAO-CHUN TSENG, Hsinchu City (TW)

(21) Appl. No.: 18/934,170

(22) Filed: Oct. 31, 2024

(30) Foreign Application Priority Data
Nov. 7, 2023 (TW) 112142801

(51) Int. Cl. G01R 31/28; G01R 3/00

(52) U.S. Cl. CPC G01R 31/2889; G01R 3/00

(57) ABSTRACT

A testing apparatus for integrated circuits (ICs) that includes a printed circuit board (PCB) incorporating a test circuit is provided. The testing apparatus includes an insulating support structure and multiple conductive pillars. The insulating support structure features several through-holes designed to accommodate the conductive pillars. The conductive pillars are partially embedded within the insulating support structure and extend through the through-holes to establish electrical connections for IC testing. These conductive pillars possess elasticity, enabling them to adapt to various sizes and shapes of ICs. The insulating support structure includes multiple grooves adjacent to the through-holes, wherein portions of the conductive pillars are embedded to enhance their secure attachment to the insulating support structure. The testing apparatus also includes an isolation layer located adjacent to the conductive pillars to prevent the pillars from contacting each other and causing short circuits. Moreover, the invention provides a method for manufacturing the testing apparatus.

### FIELD OF THE DISCLOSURE

The present invention relates to the field of integrated circuit (IC) testing apparatuses. More specifically, the invention pertains to methods for manufacturing printed circuit boards (PCBs) with directly integrated elastic conductive pillars and the resulting IC testing apparatuses produced by these methods for testing applications.

### BACKGROUND OF THE INVENTION

In the field of electronic manufacturing, testing is a critical phase to ensure the functionality and reliability of integrated circuits (ICs). Traditional methods typically employ separate sockets or connectors attached to printed circuit boards (PCBs) to facilitate the testing process. These sockets are usually added as individual components to the PCBs, which can complicate the testing process and increase overall costs.

Moreover, separate sockets must account for warping of the PCB and tolerances in the diameters of solder balls of the IC under test. This necessitates longer elastic conductive pillars to ensure stable electrical connections, thereby increasing the manufacturing costs of conductive sockets and elevating connection impedance. Such factors significantly impact specific testing requirements and signal quality.

Therefore, there is a need for a more streamlined, cost-effective, and flexible solution that integrates sockets or connectors directly into the PCBs. An ideal method would eliminate the need for separate sockets, thereby simplifying the manufacturing process, reducing costs, and enhancing design flexibility. Additionally, the method should offer options to customize the height and shape of conductive pillars to accommodate specific testing requirements and improve signal quality.

### SUMMARY OF THE INVENTION

The present invention pertains to an IC testing apparatus and its manufacturing method, aimed at simplifying the testing process and enhancing the reliability of connections between the Device Under Test (DUT) and the testing apparatus. The IC testing apparatus includes a printed circuit board (PCB) containing a test circuit. This PCB features multiple conductive pads located on its upper surface, which are electrically connected to the test circuit. Directly integrated onto these conductive pads are multiple elastic conductive pillars. These pillars serve as the primary interface between the DUT and the PCB, eliminating the need for separate sockets and thereby simplifying the testing setup.

The IC testing apparatus also includes an isolation layer surrounding the elastic conductive pillars. This isolation layer performs dual functions: it assists in the positioning of the conductive pillars and enhances the dielectric strength between adjacent pillars. Various embodiments of the invention allow for the use of different materials for the isolation layer and the conductive particles within the elastic conductive pillars, providing flexibility in manufacturing and application.

Furthermore, the invention discloses two distinct methods for manufacturing the IC testing apparatus. The first method involves applying a sacrificial layer and/or an isolation layer to the PCB, forming a patterned space corresponding to the layout of the elastic conductive pillars, filling these spaces with conductive gel, and then curing the gel. The second method begins with providing a sacrificial layer, applying an isolation layer on top, and following similar steps to form and cure the conductive pillars, ultimately removing the sacrificial layer and attaching the conductive pillars to the PCB.

The IC testing apparatus of the invention is versatile, capable of adapting to high-speed signal applications. It also allows for specific modifications based on design specifications, such as adjusting the height of the isolation layer and selectively removing portions of the conductive gel to meet particular testing needs.

### BRIEF DESCRIPTION OF THE DRAWINGS

The objects, spirits, and advantages of the preferred embodiments of the present disclosure will be readily understood by the accompanying drawings and detailed descriptions, wherein:

FIG. 1A illustrates a sectional schematic view of the IC testing apparatus according to the present invention.

FIG. 1B illustrates a top view of the IC testing apparatus according to the present invention.

FIG. 2 illustrates a schematic diagram of the PCB pad pinout configuration on the upper surface of the printed circuit board of another embodiment of the IC testing apparatus according to the present invention.

FIG. 3 illustrates a flowchart of a first embodiment of the manufacturing method for the IC testing apparatus.

FIG. 4A to FIG. 4E illustrate schematic diagrams corresponding to each step during the manufacturing of the IC testing apparatus.

FIG. 5 illustrates a flowchart of a second embodiment of the manufacturing method for the IC testing apparatus.

FIG. 6A to FIG. 6D illustrate schematic diagrams corresponding to each step during the manufacturing of the IC testing apparatus.

FIG. 7 illustrates a flowchart of a third embodiment of the manufacturing method for the IC testing apparatus.

FIG. 8A to FIG. 8D illustrate schematic diagrams corresponding to each step during the manufacturing of the IC testing apparatus.

FIG. 9 illustrates a flowchart of a fourth embodiment of the manufacturing method for the IC testing apparatus.

FIG. 10A to FIG. 10F illustrate schematic diagrams corresponding to each step during the manufacturing of the IC testing apparatus.

### DESCRIPTION OF THE PREFERRED EMBODIMENTS

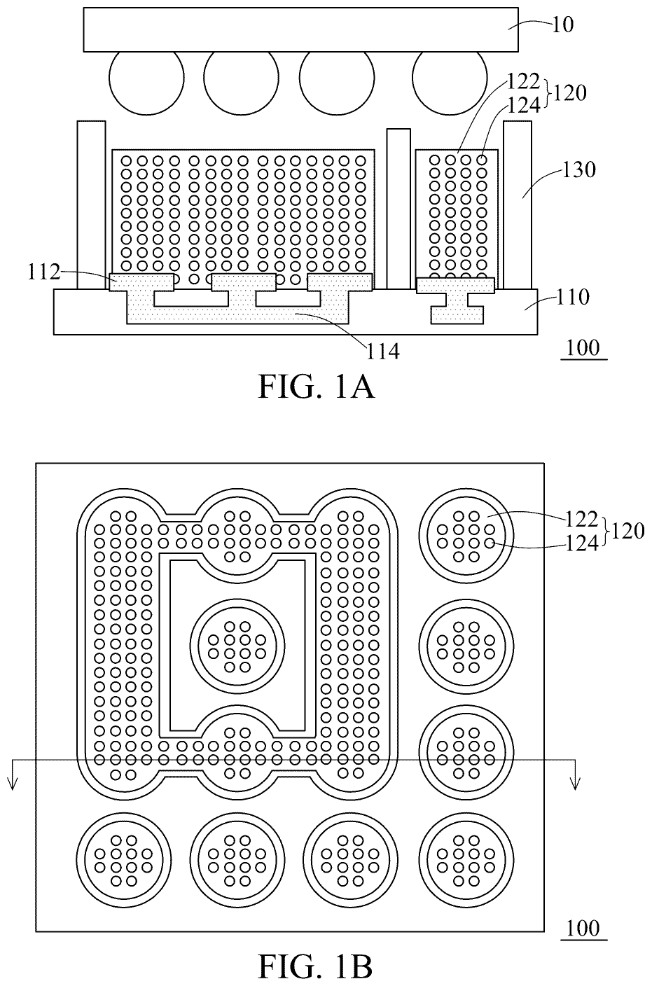

Referring to FIG. 1A and FIG. 1B, FIG. 1A illustrates a sectional schematic view of the IC testing apparatus according to the present invention, and FIG. 1B illustrates a top view of the IC testing apparatus according to the present invention. In this embodiment, the IC testing apparatus 100 primarily comprises a printed circuit board (PCB) 110 and a plurality of elastic conductive pillars 120. The printed circuit board 110 serves as the foundational component of the IC testing apparatus 100, providing structural support and electrical connections for the device under test (DUT) 10. The printed circuit board 110 includes multiple conductive pads 112 and a test circuit 114. The conductive pads 112 are located on the upper surface of the printed circuit board 110 and are electrically connected to the test circuit 114. These conductive pads 112 are designed to make electrical contact with the DUT 10.

The elastic conductive pillars 120 are formed directly on the conductive pads 112 on the upper surface of the printed circuit board 110, thereby creating a high-quality and highly conductive interface that connects the DUT 10 and the printed circuit board 110. The elastic conductive pillars 120 are flexible, allowing for a certain degree of adaptability during the testing process. This flexibility provides adaptability when the distance to the conductive pillars varies due to surface warping or solder ball diameter tolerances of the DUT 10, thereby enhancing the reliability and accuracy of the test results.

The elastic conductive pillars 120 serve as the primary interface between the DUT 10 and the printed circuit board 110. They enable the transmission of test signals while maintaining electrical connections between the DUT 10 and the printed circuit board 110. By directly integrating these elastic conductive pillars 120 into the conductive pads 112 of the printed circuit board 110, the traditional testing method using separate sockets is replaced. This structure of the IC testing apparatus 100, which directly integrates the elastic conductive pillars, reduces testing complexity and cost. Additionally, it shortens the overall distance of the test circuit, reduces test impedance, and improves the accuracy and reliability of the test results.

Surrounding the elastic conductive pillars 120 is an isolation layer 130. One of the main functions of the isolation layer 130 in the IC testing apparatus 100 is to assist in the positioning of the elastic conductive pillars 120. By surrounding the elastic conductive pillars 120, the isolation layer 130 helps maintain their positions on the conductive pads 112 of the printed circuit board 110, ensuring that they remain correctly positioned to establish the required electrical connections with the DUT 10. This is crucial for achieving accurate and reliable test results.

In addition to its positioning assistance function, the isolation layer 130 also helps enhance the dielectric strength of the IC testing apparatus 100. Dielectric strength refers to the maximum electric field that a material can withstand without breaking down under an applied voltage. By enhancing the dielectric strength, the isolation layer 130 helps prevent electrical damage or short circuits during the testing process and can shield against electromagnetic interference (EMI) caused by electron migration, thereby improving the reliability and safety of the IC testing apparatus 100.

The isolation layer 130 can be composed of various materials, depending on the specific requirements of the IC testing apparatus 100. Some possible materials for the isolation layer 130 include polyamide, PCB materials, silicone, and ceramics. The choice of material for the isolation layer 130 can be customized based on the specific requirements of the IC testing apparatus 100, providing flexibility in the design and manufacturing process.

In this embodiment, the elastic conductive pillars 120 are designed to be detachable, offering a certain degree of versatility and efficiency. The detachability of the elastic conductive pillars 120 allows them to be easily removed from the conductive pads 112 of the printed circuit board 110, facilitating their replacement or repositioning according to different testing conditions or requirements. This feature provides flexibility in adjusting the positioning or configuration of the elastic conductive pillars when the DUT 10 or the IC testing apparatus 100 changes from one test to another.

Furthermore, these IC testing apparatuses 100 are designed to be reusable, meaning they can be used multiple times in different testing scenarios. This reusability enhances the cost-effectiveness of the IC testing apparatus 100 by reducing the number of elastic conductive pillars 120 that need to be manufactured and integrated onto the conductive pads 112 of the printed circuit board 110. It also contributes to the environmental sustainability of the IC testing apparatus 100 by reducing the material waste generated during the testing process.

The elastic conductive pillars 120 are composed of a conductive colloid 122 and conductive particles 124 embedded within the elastic conductive colloid 122. Through the conductive particles 124, the elastic conductive pillars 120 can establish electrical connections between the DUT 10 and the printed circuit board 110. These conductive particles 124 can be made from various materials, depending on the specific requirements of the IC testing apparatus 100. Some possible materials for the conductive particles 124 include metal powders, metal alloy powders, graphite powders, conductive compounds, and conductive plastics.

The choice of material for the conductive particles 124 can be customized based on the specific requirements of the IC testing apparatus 100, providing flexibility in the design and manufacturing process. By selecting appropriate materials for the conductive particles 124, the performance of the elastic conductive pillars 120 can be optimized, thereby enhancing the overall performance of the IC testing apparatus 100.

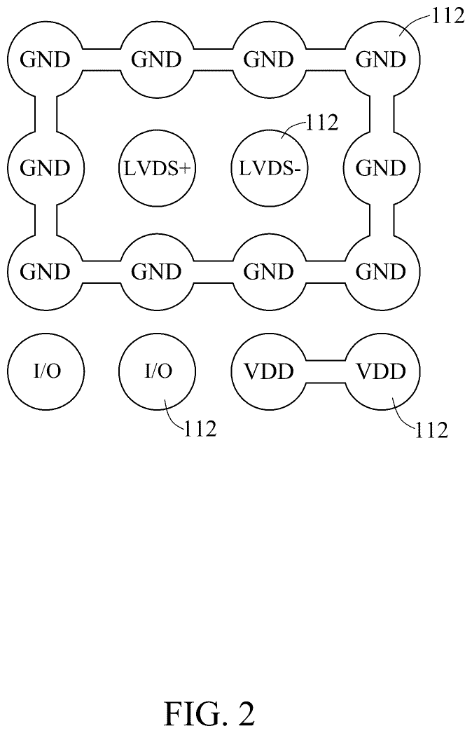

Referring also to FIG. 2, FIG. 2 illustrates another embodiment of the IC testing apparatus according to the present invention, showing a schematic diagram of the PCB pad pinout configuration on the upper surface of the printed circuit board. The configuration of the conductive pads 112 on the printed circuit board in the IC testing apparatus is noteworthy. The conductive pads 112 are strategically distributed on the printed circuit board to facilitate the various types of connections typically involved in IC testing. These types of connections include ground connections, high-frequency signal connections, power connections, and general signal connections.

Corresponding to the ground connections, the conductive pads 112 labeled as GND in FIG. 2 are uniformly distributed around the periphery of the printed circuit board 110. Ground connections are common features in electronic circuits, providing a reference point for voltages within the circuit. By uniformly distributing the ground conductive pads 112 around the periphery, a uniform ground reference is ensured across the printed circuit board, which can help stabilize and ensure reliable test results.

Corresponding to high-frequency signals, the conductive pads 112 labeled as LVDS+ and LVDS− in FIG. 2 are also included in the configuration of the conductive pads 112. LVDS, or Low-Voltage Differential Signaling, is a technology used for high-speed data transmission. It involves transmitting information as a differential voltage between two signals, which helps minimize the impact of noise and interference. By including LVDS+ and LVDS− in the configuration of the conductive pads 112, the IC testing apparatus is equipped to handle high-speed signal applications.

Corresponding to power connections, the conductive pads 112 labeled as VDD in FIG. 2 are adjacent to the conductive pads 112 labeled as I/O, which correspond to general signal connections. VDD provides power to the DUT 10, while I/O handles the input and output signals during the testing process. By placing VDD in proximity to I/O, the IC testing apparatus 100 ensures short and direct paths for power and signal connections, which helps minimize power loss and signal distortion, thereby enhancing the efficiency and accuracy of the testing process.

In summary, the configuration of the conductive pads 112 on the printed circuit board in the IC testing apparatus is a carefully considered design aspect. By strategically distributing various types of conductive pads 112 on the printed circuit board, the IC testing apparatus ensures efficient and reliable connections during the IC testing process. This contributes to the overall efficiency of the IC testing apparatus, enabling it to provide accurate and reliable test results.

Moreover, the design of the IC testing apparatus 100 in the aforementioned embodiment is particularly suitable for high-speed signal applications. This suitability is primarily due to the direct integration of the elastic conductive pillars 120 into the conductive pads 112 of the printed circuit board 110 and the strategic configuration of the conductive pads 112 on the printed circuit board 110. By directly integrating the elastic conductive pillars 120 into the conductive pads 112 of the printed circuit board, traditional separate sockets are eliminated. Eliminating these individual sockets allows for a reduction in the height of the elastic conductive pillars and decreases the possibility of signal loss or distortion at the socket interfaces. This is especially advantageous for high-speed signal applications. Additionally, the direct integration of the elastic conductive pillars 120 simplifies the structure of the IC testing apparatus 100, reducing manufacturing complexity and cost.

Referring specifically to FIG. 1A, the height of the isolation layer 130 surrounding the elastic conductive pillars 120 is another adjustable characteristic of the IC testing apparatus 100 in this embodiment. This height can be adjusted to be between 0.2 to 4 times the height of the elastic conductive pillars 120. This range provides a degree of flexibility in the design of the IC testing apparatus 100, allowing it to be tailored according to the testing scenarios or specific requirements of the DUT 10.

For example, in certain cases, a relatively lower height for the isolation layer 130 may be more advantageous. This could be the case when the DUT 10 is relatively flat or when a low-profile configuration is required for the testing setup. A low-height isolation layer 130 can help minimize the overall height of the IC testing apparatus 100, making it more compact and easier to integrate into various testing equipment. Conversely, in other cases, a relatively higher height for the isolation layer 130 may be more beneficial. A high-height isolation layer 130 can provide additional insulation and shielding for the elastic conductive pillars 120, potentially enhancing signal integrity and reducing the risk of electrical interference.

Furthermore, a higher isolation layer 130 can provide additional structural support for the elastic conductive pillars 120, helping to maintain their position and alignment during the testing process. This can be particularly beneficial in situations where the DUT 10 or the IC testing apparatus 100 is subjected to mechanical stress or vibration, as the additional support from the isolation layer 130 can help preserve the integrity of the electrical connections.

Additionally, the isolation layer 130 surrounding the elastic conductive pillars 120 enhances the dielectric strength of the IC testing apparatus 100. This enhancement is particularly beneficial for high-speed signal applications, where the risk of electrical interference is high. By enhancing the dielectric strength, the isolation layer 130 helps prevent electrical damage or short circuits during the testing process, thereby improving the reliability and safety of the IC testing apparatus 100 in high-speed signal applications.

In summary, the design of the IC testing apparatus 100, which includes the direct integration of the elastic conductive pillars 120 into the conductive pads 112 of the printed circuit board 110, the strategic configuration of the conductive pads 112 on the printed circuit board 110, and the inclusion of the isolation layer 130, all contribute to its suitability for high-speed signal applications. This suitability enhances the versatility of the IC testing apparatus 100, enabling it to meet a wide range of IC testing scenarios, including those involving high-speed signals.

Referring specifically to FIG. 1B, the design of the elastic conductive pillars 120 is also a noteworthy aspect of the IC testing apparatus 100. These elastic conductive pillars 120 are directly integrated into the conductive pads 112 of the printed circuit board 110 and are characterized by multiple different cross-sectional shapes and lateral connections. By integrating the elastic conductive pillars 120 into the test circuit board 110, the elastic conductive pillars 120 above the conductive pads 112 with the same electrical potential are laterally connected to each other, forming a pillar with a larger cross-sectional area. This increases the overall area of the elastic conductive pillars, enhancing their tolerance when the DUT 10 is pressed during testing, significantly extending the lifespan of the elastic conductive pillars 120, and preventing the occurrence of voltage differences of conductive pads with the same electrical potential. These design features substantially contribute to the functionality of the IC testing apparatus 100. The elastic conductive pillars 120 can also be designed in various cross-sectional shapes, such as circular, rectangular, square, or polygonal shapes, depending on the specific requirements of the IC testing apparatus 100.

Furthermore, the lateral connections between the elastic conductive pillars 120 can also contribute to the mechanical stability of the IC testing apparatus 100. By connecting the elastic conductive pillars 120, the IC testing apparatus 100 creates a network of elastic conductive pillars that can support each other during the testing process. This can be particularly beneficial in situations where the DUT 10 or the IC testing apparatus 100 is subjected to mechanical stress or vibration, as the interconnected network of elastic conductive pillars 120 helps maintain the integrity of the electrical connections.

In summary, the design of the elastic conductive pillars 120, including their multiple different cross-sectional shapes and lateral connections, is a feature of the IC testing apparatus 100 in this embodiment. By customizing the design of the elastic conductive pillars 120 according to the specific requirements of the IC testing apparatus 100, the IC testing apparatus 100 can optimize its electrical performance, mechanical stability, and overall design flexibility, thereby enhancing its efficiency and reliability in the IC testing process.

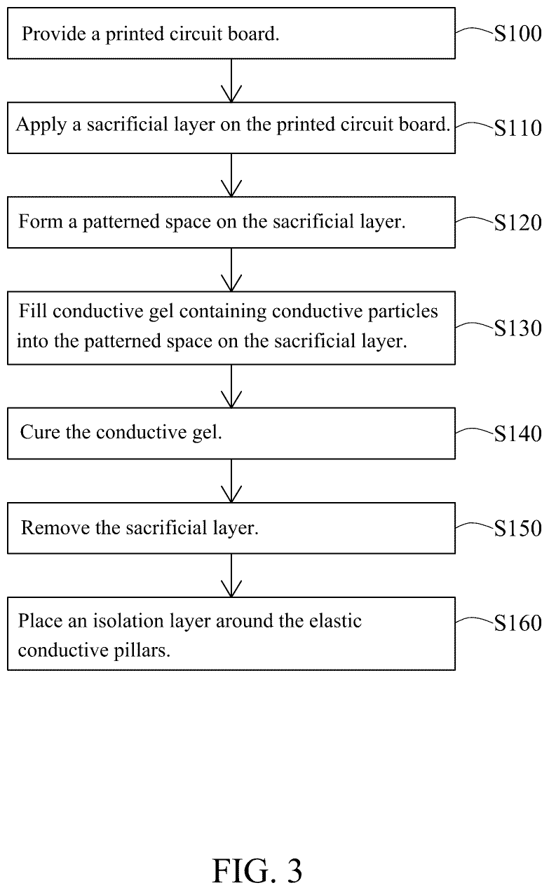

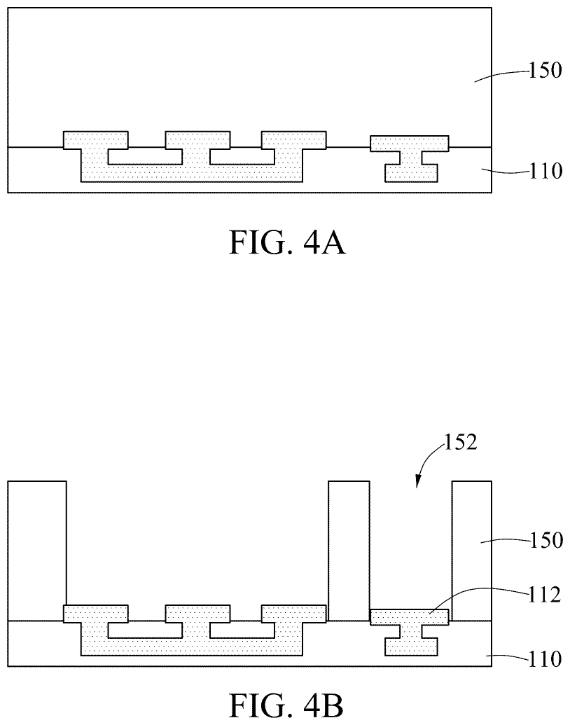

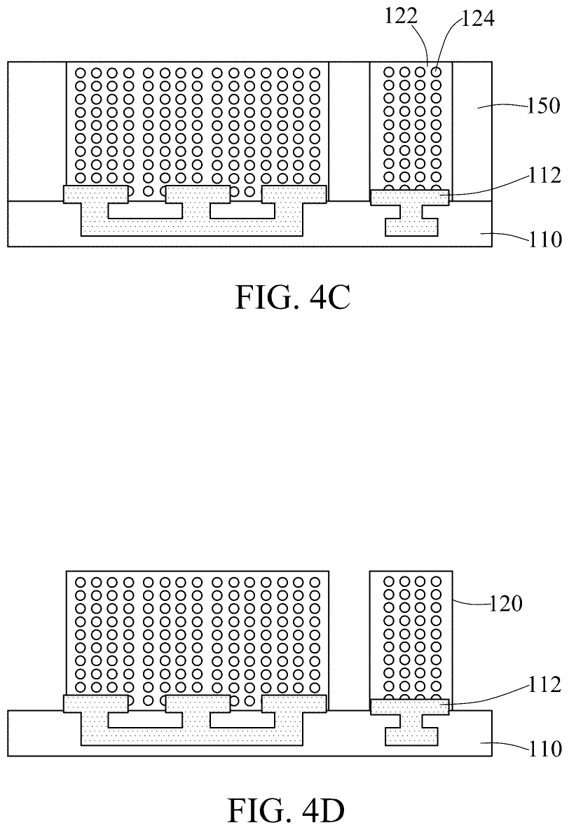

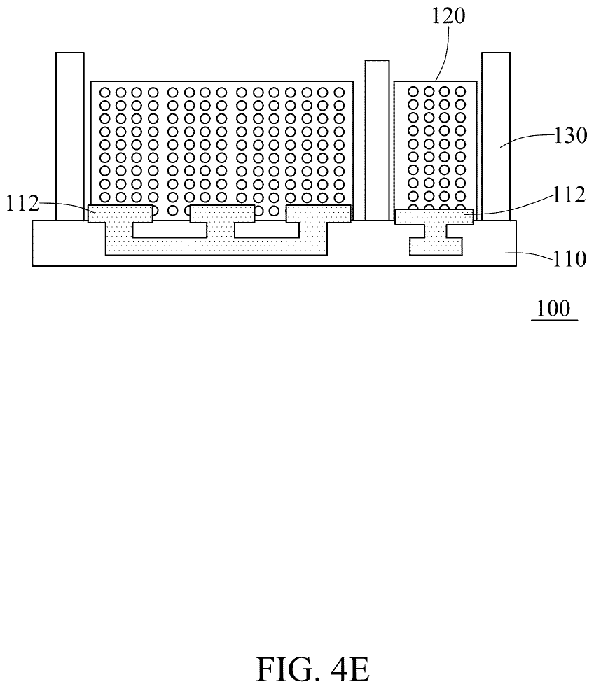

Below, the manufacturing process for the aforementioned IC testing apparatus 100 will be described. Reference is made to FIG. 3 and FIG. 4A to FIG. 4E. FIG. 3 illustrates a flowchart of a first embodiment of the manufacturing method for the IC testing apparatus, and FIG. 4A to FIG. 4E illustrate schematic diagrams corresponding to each step during the manufacturing of the IC testing apparatus.

Firstly, a printed circuit board (PCB) 110 is provided. Then, in step S110, as shown in FIG. 4A, a sacrificial layer 150 is applied to the printed circuit board 110. The sacrificial layer 150 can be composed of various materials, such as a photoresist layer or polyimide (PI), depending on the specific requirements during the manufacturing of the IC testing apparatus.

After applying the sacrificial layer 150, step S120 is performed, as shown in FIG. 4B, to form a patterned space 152 on the sacrificial layer 150 corresponding to the layout of the elastic conductive pillars 120. This patterned space 152 defines the positions and shapes of the elastic conductive pillars 120, ensuring their precise positioning on the conductive pads 112 of the printed circuit board 110. Various techniques, such as photolithography or laser etching, can be used to create the patterned space 152, depending on the complexity of the layout of the elastic conductive pillars 120 and the precision requirements of the IC testing apparatus 100.

After forming the patterned space 152, step S130 is executed, as shown in FIG. 4C, to fill the patterned space 152 on the sacrificial layer 150 with conductive gel 122 containing conductive particles 124. This conductive gel 122 serves as the primary material for the elastic conductive pillars 120. The conductive gel 122 and conductive particles 124 are carefully selected to provide the required conductivity and mechanical flexibility for the elastic conductive pillars 120. Appropriate techniques, such as spin coating, can be used to fill the conductive gel 122 and conductive particles 124 into the patterned space 152, ensuring uniform and precise filling of the conductive gel 122.

After filling the conductive gel 122, step S140 is performed to cure the conductive gel 122. This process involves exposing the conductive gel 122 to an appropriate curing agent or curing conditions (such as heat or ultraviolet light), causing the conductive gel 122 to solidify and stabilize. The curing process ensures that the conductive gel 122 maintains its shape and provides a consistent conductive path for the electrical connections between the device under test (DUT) 10 and the printed circuit board 110.

Once the conductive gel 122 is cured, step S150 is executed, as shown in FIG. 4D, to remove the sacrificial layer 150. Removing the sacrificial layer 150 allows the elastic conductive pillars 120 to stand directly on the conductive pads 112 of the printed circuit board 110. Appropriate techniques, such as dissolution or peeling, can be used to remove the sacrificial layer 150, depending on the material of the sacrificial layer 150 and the specific requirements of the IC testing apparatus 100.

Subsequently, step S160 is performed, as shown in FIG. 4E, to place the isolation layer 130 around the elastic conductive pillars 120. The isolation layer 130 can be pre-shaped to match the shape of the conductive pillars 120 before placement or can be applied using a coating method. The isolation layer 130 serves multiple purposes in the IC testing apparatus 100. It assists in positioning the elastic conductive pillars 120, maintaining their precise alignment on the conductive pads 112 of the printed circuit board 110. Additionally, it enhances the dielectric strength of the IC testing apparatus 100, providing effective protection against electrical interference.

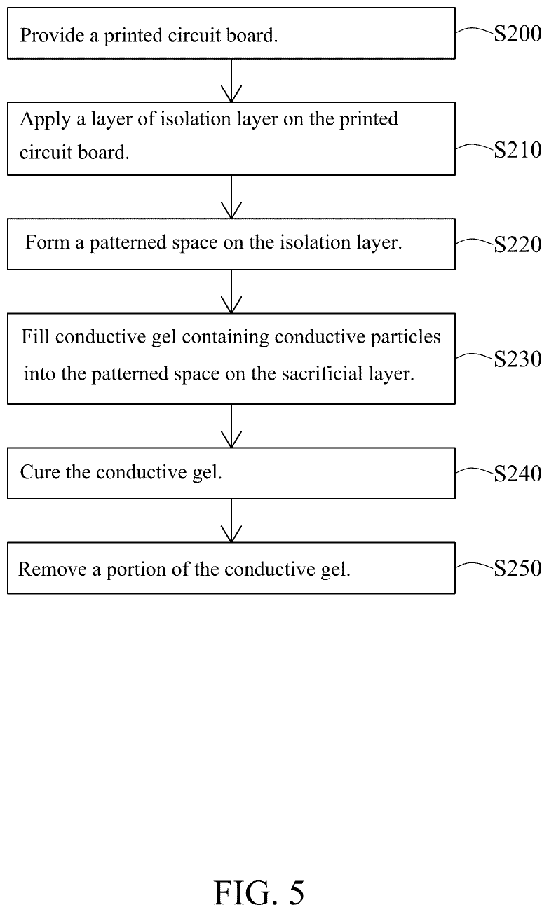

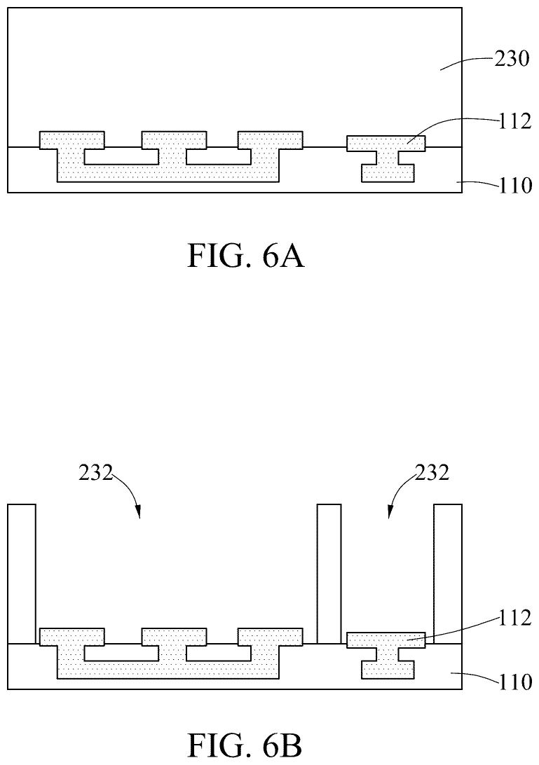

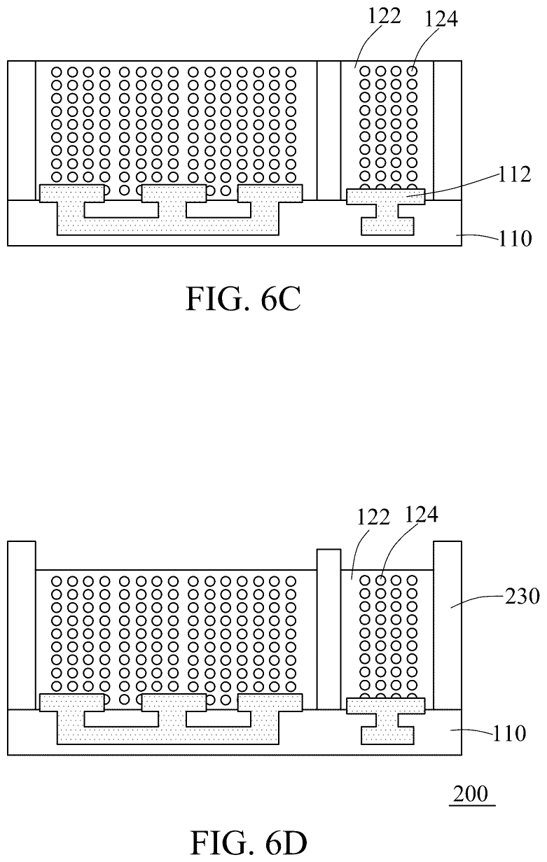

Next, reference is made to FIG. 5 and FIG. 6A to FIG. 6D. FIG. 5 illustrates a flowchart of a second embodiment of the manufacturing method for the IC testing apparatus, and FIG. 6A to FIG. 6D illustrate schematic diagrams corresponding to each step during the manufacturing of the IC testing apparatus.

Firstly, in step S210, as shown in FIG. 6A, a printed circuit board 110 is provided. Then, a layer of isolation layer 230 is applied to the printed circuit board 110. This isolation layer 230 acts as an insulating and shielding layer, ensuring signal integrity and reducing interference. The isolation layer 230 can be composed of various materials, such as polyamide, PCB materials, silicone, or ceramics, depending on the specific requirements of the IC testing apparatus. The application of the isolation layer 230 can be performed using appropriate techniques, such as coating or deposition, to ensure uniform and precise coverage of the isolation layer 230.

After applying the isolation layer 230, step S220 is executed, as shown in FIG. 6B, to form a patterned space 232 on the isolation layer 230 corresponding to the layout of the elastic conductive pillars 120. This patterned space 232 defines the positions and shapes of the elastic conductive pillars 120, ensuring their precise positioning on the conductive pads 112 of the printed circuit board 110. Various techniques, such as photolithography or laser etching, can be used to create the patterned space 232, depending on the complexity of the layout of the elastic conductive pillars 120 and the precision requirements of the IC testing apparatus.

After forming the patterned space 232, step S230 is executed, as shown in FIG. 6C, to fill the patterned space 232 on the isolation layer 230 with conductive gel 122 and conductive particles 124. After filling the conductive gel 122, step S240 is performed to cure the conductive gel 122.

In one embodiment, step S250 can also be performed, as shown in FIG. 6D, to remove a portion of the conductive gel 122 according to design requirements. This step allows the manufacturer to customize the configuration and functionality, adapting to specific testing needs or improving signal quality by altering the height or shape of the elastic conductive pillars 120. Partial removal of the conductive gel 122 can be achieved using appropriate techniques, such as etching or laser stripping, depending on the material of the conductive gel 122 and the specific requirements of the IC testing apparatus 200.

As can be seen from FIG. 6D, in the second embodiment, the isolation layer 230 in the manufactured IC testing apparatus 200 is closely adhered to the elastic conductive pillars 120, which differs from the first embodiment, where there may be a gap between the isolation layer 130 and the elastic conductive pillars 120.

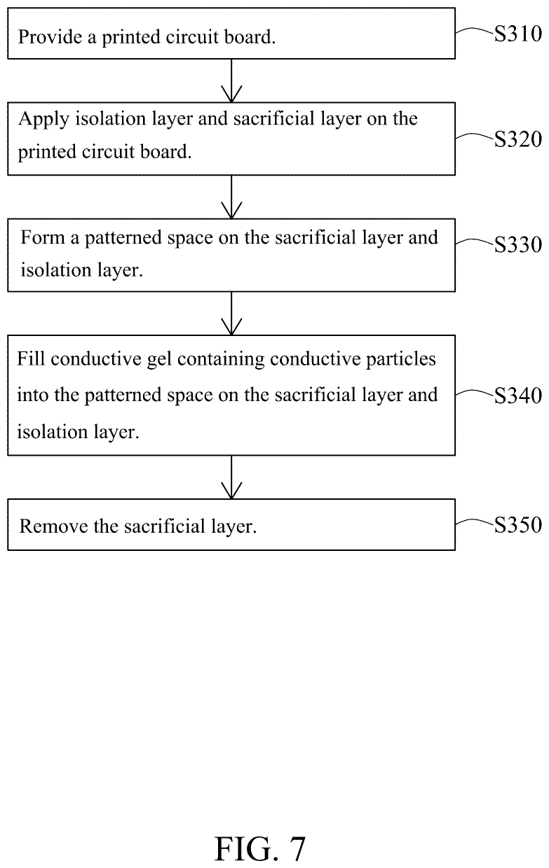

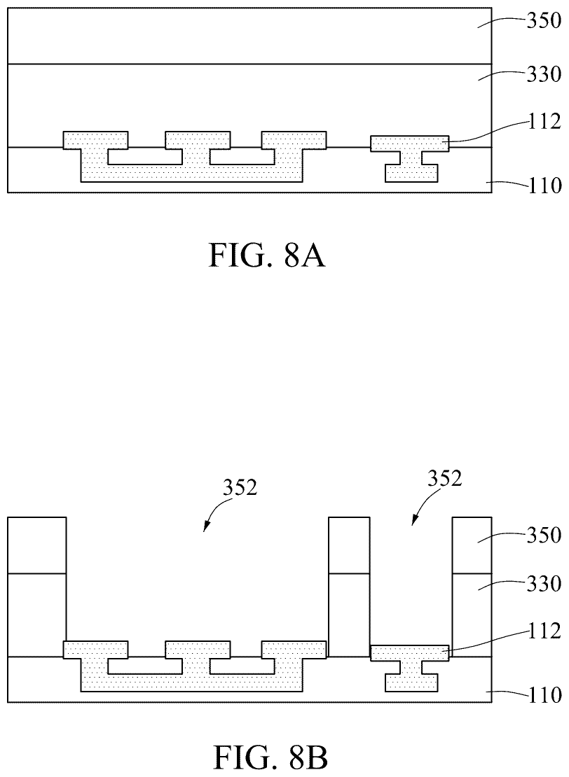

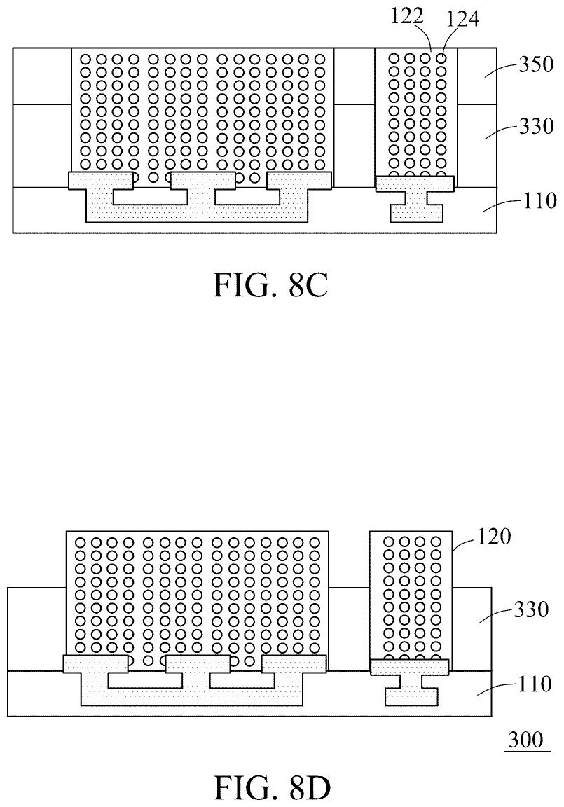

Next, reference is made to FIG. 7 and FIG. 8A to FIG. 8D. FIG. 7 illustrates a flowchart of a third embodiment of the manufacturing method for the IC testing apparatus, and FIG. 8A to FIG. 8D illustrate schematic diagrams corresponding to each step during the manufacturing of the IC testing apparatus.

Firstly, in step S310, a printed circuit board 110 is provided, which includes multiple conductive pads 112. Then, in step S320, as shown in FIG. 8A, a layer of isolation layer 330 and a sacrificial layer 350 are applied to the printed circuit board 110. In the IC testing apparatus, the isolation layer 330 acts as an insulating and shielding layer, ensuring signal integrity and reducing interference. The isolation layer 330 can be composed of various materials, such as polyamide, PCB materials, silicone, or ceramics. The application of the isolation layer 330 can be performed using appropriate techniques, such as coating or deposition, to ensure uniform and precise coverage of the isolation layer 330. The sacrificial layer 350 is uniformly applied over the isolation layer 330 and can be composed of various materials, such as a photoresist layer or polyimide (PI).

After applying the isolation layer 330 and the sacrificial layer 350, step $330 is executed, as shown in FIG. 8B, to form a patterned space 352 on the sacrificial layer 350 and the isolation layer 330 corresponding to the layout of the elastic conductive pillars 120. This patterned space 352 defines the positions and shapes of the elastic conductive pillars 120, ensuring their precise positioning on the conductive pads 112 of the printed circuit board. Various techniques, such as photolithography or laser etching, can be used to create the patterned space 352.

After forming the patterned space 352, step S340 is executed, as shown in FIG. 8C, to fill the patterned space 352 on the sacrificial layer 350 and the isolation layer 330 with conductive gel 122 and conductive particles 124. After filling the conductive gel 122, step S350 is performed, as shown in FIG. 8D, to remove the sacrificial layer 350, leaving the elastic conductive pillars 120 standing directly on the conductive pads 112 of the printed circuit board 110, surrounded by the isolation layer 330, thereby forming the IC testing apparatus 300. One characteristic of the IC testing apparatus 300 manufactured by the third embodiment is that the height of the elastic conductive pillars 120 is higher than that of the isolation layer 330.

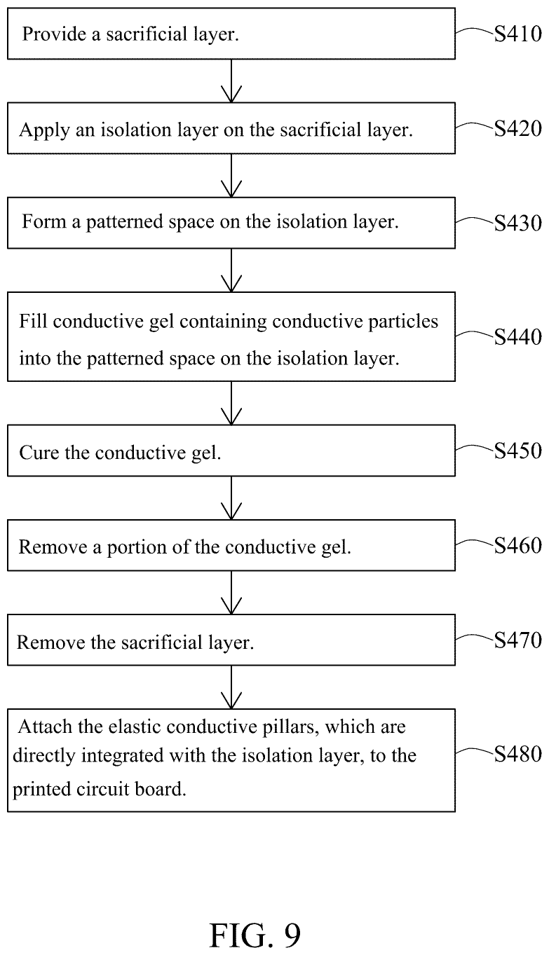

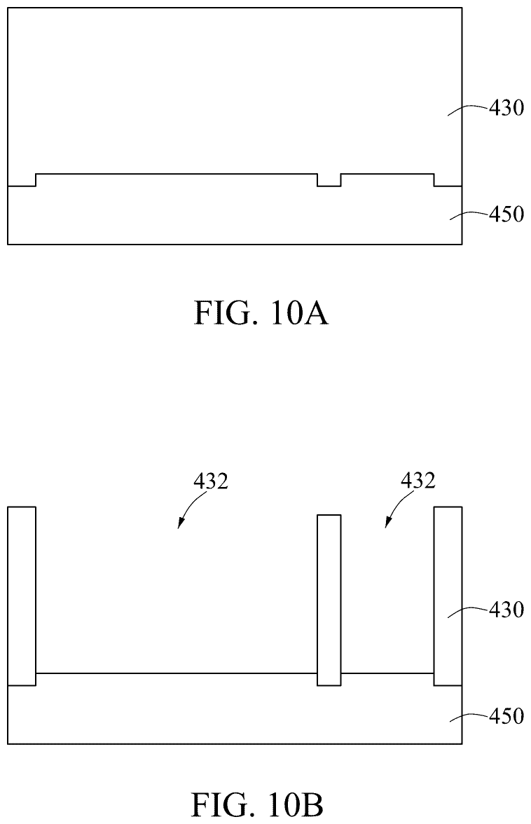

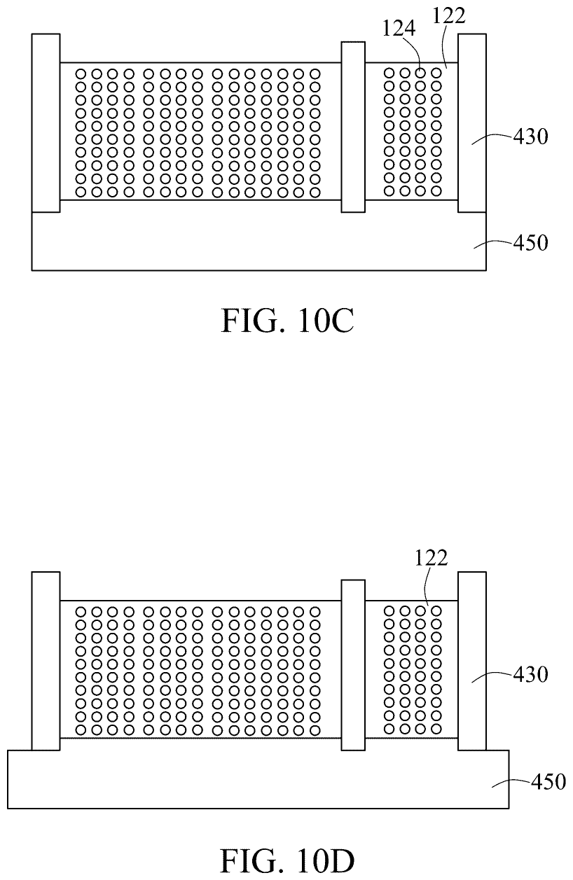

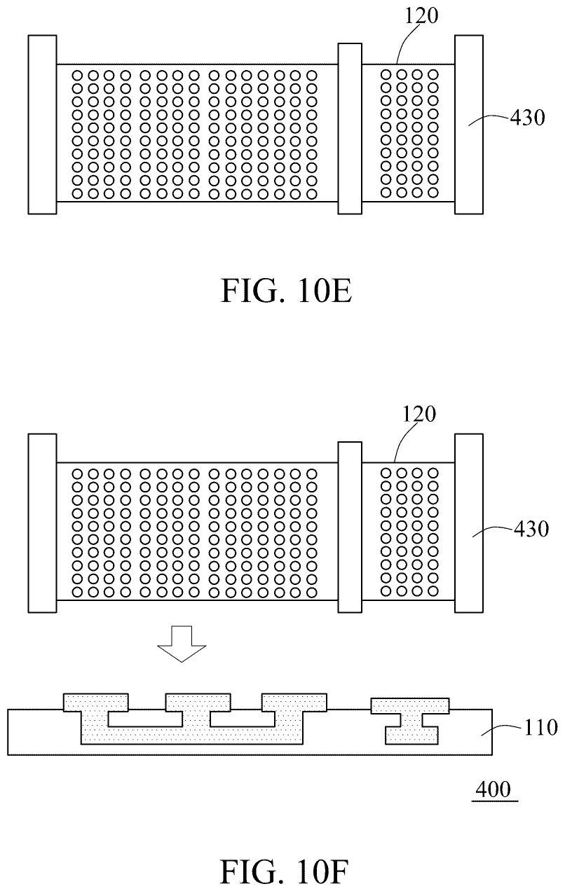

Next, reference is made to FIG. 9 and FIG. 10A to FIG. 10F. FIG. 9 illustrates a flowchart of a fourth embodiment of the manufacturing method for the IC testing apparatus, and FIG. 10A to FIG. 10F illustrate schematic diagrams corresponding to each step during the manufacturing of the IC testing apparatus.

As shown in step S410, the manufacturing of the fourth embodiment of the IC testing apparatus begins by providing a sacrificial layer 450. This sacrificial layer 450 acts as a temporary substrate during the manufacturing process, providing a temporary surface for subsequent steps. The sacrificial layer 450 can be composed of various materials, such as a photoresist layer or polyimide (PI).

Once the sacrificial layer is provided, step S420 is executed, as shown in FIG. 10A, to apply an isolation layer 430 on the sacrificial layer 450. After applying the isolation layer 430, step S430 is performed, as shown in FIG. 10B, to form a patterned space 432 on the isolation layer 430 corresponding to the layout of the elastic conductive pillars 120. This patterned space 432 defines the positions and shapes of the elastic conductive pillars 120, ensuring their precise positioning.

After forming the patterned space 432, step S440 is executed, as shown in FIG. 10C, to fill the patterned space 432 on the isolation layer 430 with conductive gel 122 and conductive particles 124. After filling the conductive gel 122 and conductive particles 124, step S450 is performed to cure the conductive gel 122.

In one embodiment, step S460 can also be performed, as shown in FIG. 10D, to remove a portion of the conductive gel 122 according to design requirements. Step S460 is an optional step, meaning that the designer of the IC testing apparatus may choose not to perform this step as needed.

Subsequently, step S470 is executed, as shown in FIG. 10E, to remove the sacrificial layer 450, leaving the elastic conductive pillars 120, which are now directly integrated with the isolation layer 430. Removing the sacrificial layer 450 can be accomplished using appropriate techniques, such as dissolution or peeling.

Then, step S480 is performed, as shown in FIG. 10F, to directly attach the elastic conductive pillars 120, now directly integrated with the isolation layer 430, to the printed circuit board 110, thereby completing the manufacturing of the IC testing apparatus 400. The attachment of the elastic conductive pillars 120 to the printed circuit board 110 can be performed using appropriate techniques, such as soldering or bonding, depending on the materials of the elastic conductive pillars 120 and the specific requirements of the IC testing apparatus 400.

Although the invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

1. An IC testing apparatus, comprising:
a printed circuit board including a test circuit;
a plurality of conductive pads located on an upper surface of the printed circuit board and electrically connected to the test circuit; and
a plurality of elastic conductive pillars directly integrated onto the conductive pads of the printed circuit board.

2. The IC testing apparatus of claim 1, further comprising an isolation layer surrounding the elastic conductive pillars.

3. The IC testing apparatus of claim 2, wherein the distance between the isolation layer and the elastic conductive pillars is greater than 0.

4. The IC testing apparatus of claim 1, wherein the elastic conductive pillars have a plurality of different cross-sectional shapes.

5. The IC testing apparatus of claim 1, wherein the material of the isolation layer is selected from the group consisting of polyamide, PCB materials, silicone, and ceramics.

6. The IC testing apparatus of claim 1, wherein a plurality of conductive particles is embedded within the elastic conductive pillars and the conductive particles are selected from the group consisting of metal powders, metal alloy powders, graphite powders, conductive compounds, and conductive plastics.

7. The IC testing apparatus of claim 2, wherein the height of the isolation layer is approximately 0.2 to 4 times the height of the elastic conductive pillars.

8. The IC testing apparatus of claim 1, wherein the elastic conductive pillars are laterally connected to conductive pads which supply the same electrical potential.

9. A method of manufacturing an IC testing apparatus, comprising the steps of:
providing a printed circuit board including a test circuit;
forming a plurality of conductive pads electrically connected to the test circuit on an upper surface of the printed circuit board; and
forming a plurality of elastic conductive pillars on the conductive pads.

10. The method of claim 9, wherein the step of forming the elastic conductive pillars on the conductive pads comprises:
forming a sacrificial layer on the printed circuit board;
forming a plurality of patterned spaces on the sacrificial layer to expose the conductive pads;
filling conductive gel into the patterned spaces and curing the conductive gel; and
removing the sacrificial layer.

11. The method of claim 9, further comprising forming an isolation layer on the printed circuit board, the isolation layer surrounding the elastic conductive pillars.

12. The method of claim 11, wherein the step of forming the isolation layer on the printed circuit board comprises:
forming a sacrificial layer on the printed circuit board;
forming a plurality of patterned spaces on the sacrificial layer to expose the conductive pads;
filling conductive gel into the patterned spaces and curing the conductive gel.

13. The method of claim 11, wherein the step of forming the isolation layer on the printed circuit board comprises:
forming an isolation layer on a sacrificial layer;
forming a plurality of patterned spaces on the isolation layer;
filling conductive gel into the patterned spaces and curing the conductive gel to form a plurality of elastic conductive pillars;
removing the sacrificial layer; and
attaching the elastic conductive pillars together with the isolation layer to the printed circuit board.

14. The method of claim 11, wherein the height of the isolation layer is approximately 0.2 to 4 times the height of the elastic conductive pillars.

15. The method of claim 11, wherein a distance between the isolation layer and the elastic conductive pillars is greater than 0.

16. The method of claim 11, wherein the material of the isolation layer is selected from the group consisting of polyamide, PCB materials, silicone, and ceramics.

17. The method of claim 10, wherein a plurality of conductive particles is embedded within the elastic conductive pillars and the conductive particles are selected from the group consisting of metal powders, metal alloy powders, graphite powders, conductive compounds, and conductive plastics.

18. The method of claim 9, wherein the elastic conductive pillars are laterally connected to conductive pads supplying the same electrical potential.
